(19) United States
(12) Patent Application Publication
(10) Pub. No.: US 2006/0087230 A1
(43) Pub. Date: Apr. 27, 2006

(54) Desiccant film in top-emitting OLED

(75) Inventors: Amalkumar P. Ghosh, Rochester, NY (US); Jin-Shan Wang, Pittsford, NY (US); Fridrich Vazan, Pittsford, NY (US)

Correspondence Address: Pamela R. Crocker;Eastman Kodak Company, Patent Legal Staff, 343 State Street, Rochester, NY, 14650-2201, US

(73) Assignee: Eastman Kodak Company

(21) Appl. No.: 10/970,950

(22) Filed: Oct. 22, 2004

(51) Int. Cl. H01L 51/52; H05B 33/02

(52) U.S. Cl. 313/512; 313/506; 428/68; 428/76; 428/690; 428/917; 257/100; 257/E51.02

(57) ABSTRACT

A top-emitting OLED device includes a substrate, a first electrode disposed over the substrate, and an organic EL media disposed over the first electrode. The device also includes a transparent or semitransparent second electrode disposed over the organic EL media, and a light transmissive desiccating film having a host and molecularly dispersed desiccant material in such host provided on or over the second electrode.

### CROSS REFERENCE TO RELATED APPLICATIONS

Reference is made to commonly assigned U.S. patent application Ser. No. 10/946,543 filed Sep. 21, 2004 by Jin-Shan Wang et al., entitled “Lewis Acid Organometallic Desiccant”, U.S. patent application Ser. No. 10/946,425 filed Sep. 21, 2004 by Jin-Shan Wang et al., entitled “Desiccant Having a Reactive Salt”, and commonly assigned U.S. patent application Ser. No. ______ filed ______ by Jin-Shan Wang et al., entitled “______”, the disclosures of which are herein incorporated by reference.

### FIELD OF THE INVENTION

The present invention relates to providing a desiccant for a top-emitting OLED device.

### BACKGROUND OF THE INVENTION

Various microelectronic devices require restrictions on humidity levels to be in a range of from about 2500 to below 5000 parts per million (ppm) to prevent premature degradation of device performance within a specified operating and/or storage life of the device. Control of the environment to this range of humidity levels within a packaged device is typically achieved by encapsulating the device or by sealing the device and a desiccant package within a cover. Desiccant packages include a container for receiving solid water absorbing particles (a desiccant) or providing such particles into a binder. Examples of solid water absorbing particles include molecular sieve materials, silica gel materials, calcium oxide, and calcium chloride.

Silica gel and molecular sieves are physical adsorption-type drying agents. Calcium oxide and calcium chloride are chemisorption-type drying agents. Since water adsorbed thereby is not driven off at high temperatures, they are more effective than silica gel and molecular sieves.

However, particles of calcium oxide and calcium chloride desiccants can be slow to absorb water. In addition, the handling of such particulate materials can be a problem in microelectronic devices that require clean room conditions. In addition, most desiccants are white and scatter light, or do so after absorption of water. Thus, they cannot be used in many applications where they might cover or obscure a necessary feature.

Organic light emitting diode (OLED) devices are one class of moisture sensitive electronic devices that can benefit from desiccants. However, conventional desiccants have not been used for so-called top-emitting OLED devices because of the problems noted above. Instead, the prior art teaches methods to seal hermetically top-emitting OLEDs using thin film barrier layers to limit the need for desiccants. Though very useful, it is very difficult to seal OLED devices reliably with thin film barrier layers. Pin-holes and other defects can still occur and provide pathways for moisture to enter the device.

### SUMMARY OF THE INVENTION

It is therefore an object of the present invention to provide moisture protection to a top-emitting OLED device that will not adversely affect device performance.

This object is achieved by a top-emitting OLED device comprising:

a) a substrate;

b) a first electrode disposed over the substrate;

c) an organic EL media disposed over the first electrode;

d) a transparent or semitransparent second electrode disposed over the organic EL media; and

e) a light transmissive desiccating film having a host and molecularly dispersed desiccant material in such host provided on or over the second electrode.

### ADVANTAGES

The invention provides a top-emitting OLED device that is protected from moisture thereby achieving longer lifetime and excellent device performance.

One advantage of providing the molecularly dispersed desiccant within a host is that this reduces the formation of aggregates or particles, especially if the desiccant is a metal complex or organometallic material. One common byproduct of the reaction of water with such metal-containing materials is the formation of metal oxides that are prone to aggregate and form small particles. Such aggregates and particles can absorb or scatter light.

### BRIEF DESCRIPTION OF THE DRAWINGS

FIG. 1 is a cross-sectional view of a prior art OLED device;

FIG. 2 is a plan view of a prior art OLED substrate with a first electrode and contact pads;

FIG. 3 shows the OLED of FIG. 2 after deposition of a patterned insulator layer;

FIG. 4A is a plan view of the OLED from FIG. 3 after deposition of the organic EL media and second electrode;

FIG. 4B is a cross sectional view of the OLED device of FIG. 4A taken along lines 4B;

FIG. 5 is a cross sectional view of a first embodiment of the present invention;

FIG. 6 is a cross sectional view of a second embodiment of the present invention;

FIG. 7 is a cross sectional view of a third embodiment of the present invention; and

FIG. 8 is a cross sectional view of a fourth embodiment of the present invention.

### DETAILED DESCRIPTION OF THE INVENTION

The present invention uses a light transmissive desiccating film having a host and a molecularly dispersed desiccant material in the host. The light transmissive desiccating film is provided in a top-emitting OLED device such that light produced in the OLED passes through the light transmissive desiccating film. The molecularly dispersed desiccant should be light transmissive both before and after water absorption.

Preferred desiccants for use in the present invention include metal complexes and organometallic materials. These desiccant materials are transparent before and after absorbing water. A “molecularly dispersed desiccant” is a water reactive molecule or a water reactive functional group provided within an inert “host” so that such reactive molecule or group is diluted relative to a pure film of the desiccant. Molecularly dispersed desiccants are discussed in more detail below. An advantage of providing the molecularly dispersed desiccant within a host is that this reduces the formation of aggregates or particles, especially if the desiccant is a metal complex or organometallic material. One common byproduct of the reaction of water with such metal-containing materials is the formation of metal oxides that are prone to aggregate and form small particles. Such aggregates and particles can absorb or scatter light. This is undesirable when light is emitted through the desiccant.

The term “transparent” means that sufficient light will pass through to form a light image. More than 75% transparency is preferred.

One class of useful desiccant material includes a Lewis acid organometallic structure that, when it reacts with water, forms a carbon-hydrogen bond but does not form an alcohol. Alcohols can adversely affect the performance of an OLED device if they are permitted to diffuse into the OLED device. This class of material limits this concern. In one preferred embodiment, the Lewis acid has the structure shown in Formula (I)
R¹ₙ-M-R²ₘ (I)
wherein:

M is a metal;

R¹ is an organic substituent wherein at least one carbon is directly bonded to the metal;

R² is a silyl oxide substituent wherein the oxygen is directly bonded to the metal, or an amide substituent having a nitrogen directly bonded to the metal; and

n=1, 2, 3, or 4 and m=0, 1, 2, or 3 and are selected to fulfill the coordination requirements of M so that Formula I is neutral in charge.

Metals selected from Group IIB, IIIA, IIIB, or IVB, or first row transition metals are useful in present invention. Preferably, they are Al, Zn, Ti, Mg, or B.

When more than one R¹ substituent is used, the R¹ substituents can be the same or different from each other. Likewise, when more than one R² substituent is used, the R² substituents can be the same or different from each other.

Some useful examples of organic substituents that can be used as R¹ include alkyl, alkenyl, aryl, and heteroaryl compounds where a saturated or unsaturated carbon is bonded to the metal. These compounds can be further substituted with alkyl, alkenyl, aryl, heteroaryl, halogen, cyano, ether, ester, or tertiary amine groups, or combinations thereof. Some non-limiting examples of R¹ methyl, ethyl, n-propyl, n-butyl, n-pentyl, n-hexyl, n-heptyl, n-octyl, i-propyl, t-butyl, cyclohexyl, tetradecyl, octadecyl, benzyl, phenyl, and pyridyl. In addition, R¹ can be part of an oligomeric or polymeric system. For example, R¹ can be a part of a polystyrene, polybutadiene, polymethacrylate, polysiloxane, or polyfluorene structure.

Silyl oxides with the following Formula II can be selected as R² for the present invention 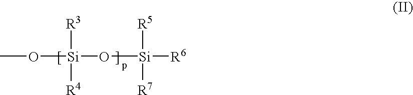
wherein R³ through R⁶ are organic substituents and p is an integer from 0 to 1000. Some organic substituents useful for R³ through R⁶ include alkyl, alkenyl, aryl, and heteroaryl compounds, which can be further substituted with alkyl, alkenyl, aryl, heteroaryl, halogen, cyano, ether, ester, or tertiary amine groups, or combinations thereof. Preferably R³ through R⁶ are alkyl or aryl groups.

Amides with the following Formula III can be selected as R² for the present invention 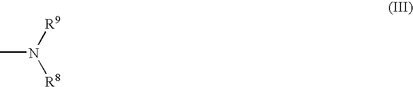
wherein R⁸ and R⁹ are organic substituents. Some organic substituents useful for R⁸ and R⁹ include alkyl, alkenyl, aryl, and heteroaryl compounds, which can be further substituted with alkyl, alkenyl, aryl, heteroaryl, halogen, cyano, ether, ester, or tertiary amine groups, or combinations thereof. R⁸ and R⁹ can be joined to form a ring system. R⁸ or R⁹ or both can be part of an oligomeric or polymeric system. For example, R⁸ or R⁹ can be a part of a polystyrene, polybutadiene, polymethacrylate, polysiloxane, or polyfluorene structure.

Although not shown in Formula I, there can be additional, non charge-bearing moieties weakly or strongly coordinated to the metal center. For example, there can be solvent molecules coordinated to the metal center in addition to R¹.

Examples of useful desiccant materials for practicing the present invention include, but are not limited to, Al(C₂H₅)₃, Al(C₄H₉)₃, B(C₄H₉)₃, Zn(C₄H₉)₂, Al(t-butyl)₃, Ti(t-butyl)₄, Mg(t-butyl)₂, Al(C₄H₉)₂(N(C₆H₅)₂), Al(C₄H₉)(N(C₆H₅)₂)₂, and the structures shown below:

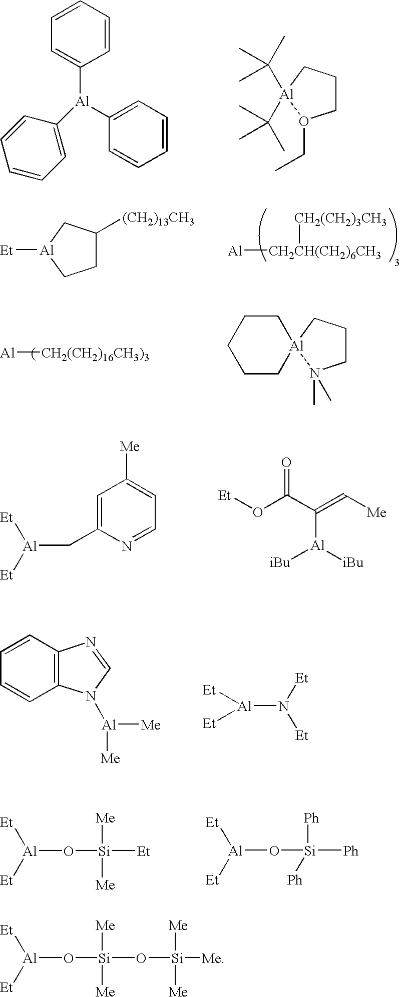

Equations 1-3 show how these moisture-absorbing materials react with water, using various examples of R¹ and R² Formula I wherein M is aluminum. For example:
Al(C₄H₉)₃+3H₂O→3C₄H₁₀+Al(OH)₃ (1)
Al(C₄H₉)((OSi(CH₃)₂)₅₀C₂H₅)₂+3H₂O→C₄H₁₀+2Si(OH)(CH₃)₂)₅₀C₂H₅+Al(OH)₃ (2)
Al(C₄H₉)₂(N(C₆H₅)₂)+3H₂O+2C₄H₁₀+2NH(C₆H₅)₂+Al(OH)₃ (3).

As can be seen, R¹ of all compounds reacts with water to form a carbon-hydrogen bond. In the case of R² the reaction with water forms a silyl oxygen-hydrogen bond or a nitrogen-hydrogen bond. None of these substituents form harmful alcohol species. The reaction products are also substantially transparent to visible light. In some instances, it can be advantageous to avoid the build up gaseous byproducts. When this is desired, R¹ and R² should be selected to have 6 or more carbon atoms so that their reaction products with water have a low vapor pressure at temperatures less than 50° C.

Methods for synthesizing the Lewis acid organometallic desiccant of the present invention can be found in Salt Effects in Organic and Organometallic Chemistry, VCH Publishers, Inc, New York, 1992.

Another useful desiccant material for practicing the present invention includes a reactive salt of a negatively charged organometallic complex that, when it reacts with water, forms a carbon-hydrogen bond but does not form an alcohol. In a preferred embodiment, the reactive salt has the structure shown in Formula (IV)
(A^{+b})_{c}[M(R¹)ₙ(R²)ₘ(X)ₗ]^{-q} (IV)
wherein:

A is a cation having charge b;

M is a metal;

R¹ is an organic substituent wherein at least one carbon is directly bonded to the metal;

R² is a silyl oxide wherein the oxygen is directly bonded to the metal, or an amide having a nitrogen directly bonded to the metal;

X is an anionic substituent having a pKa<7;

l=1 or 2

n=1, 2, 3, or 4;

m=0, 1, 2, or 3;

q=is the charge of the anionic organometallic complex and is 1 or 2; and

b=q/c.

Metals selected from Group IIB, IIIA, IIIB, or IVB, or first row transition metals are useful in present invention. Preferably, they are Al, Zn, Ti, Mg, or B.

When more than one R¹ substituent is used, the R¹ substituents can be the same or different from each other. Likewise, when more than one R² or X substituent is used, the R² or X substituents can be the same or different from each other.

Some useful examples of R¹ and R² are those previously described in relation to Formula I.

The substituent X can be an inorganic anionic material such as fluoride, chloride, bromide, iodide, nitrate, sulfate, tetrafluoroborate, hexafluorophosphate, or perchlorate. Alternatively, X can be an organic anionic material including a carboxylate, a sulfonate, or a phosphonate. When X is organic, it can be part of an oligomeric or polymeric system. Some examples of organic materials suitable for X include acetate, formate, succinate, toluenesulfonate, and polystyrenesulfonate.

The cation A can be a positively charged metal ion such as an alkali, alkaline, or alkaline earth metal. Cation A can be a positively charged metal complex, for example, a complex of an alkali, alkaline, or alkaline earth metal with a crown ether, an alkylpolyamine, or the like. Alternatively, cation A can be a positively charged organic compound. Preferred positively charged organic compounds include those that contain nitrogen or phosphorous. Some examples of positively charged organic compounds suitable as cation A include tetraalkylammonium, alkylpyridinium, and tetraalkylphosphonium compounds. When cation A is a positively charged metal complex or organic compound, it can be part of an oligomeric or polymeric system such as a polyvinylpyridinium system.

Although not shown in Formula IV, there can be additional, non charge-bearing moieties weakly or strongly coordinated to the metal center. For example, there can be solvent molecules coordinated to the metal center in addition to R¹ and X.

A few non-limiting examples of useful desiccant materials for practicing the present invention include K[Al(C₂H₅)₃F], [N(CH₃)₄][Al(C₄H₉)₃Cl], [N(C₄H₉)₄][B(C₅H₅)₃F], [N-t-butylpyridinium][B(C₅H₅)₃(OC(═O)—C₅H₅)], Li₂[Zn(C₄H₉)₂Cl], and K[(i-Bu)₃Al—F—Al(i-Bu)₃].

Equation 4 shows one example of how these moisture-absorbing materials react with water
K[Al(C₂H₅)₃F]+3H₂O→3C₂H₅+Al(OH)₃+KF (4).

As can be seen, R¹ reacts with water to form a carbon-hydrogen bond. In the case of R² (not shown) the reaction with water forms a silyl oxygen-hydrogen bond or a nitrogen-hydrogen bond. None of these substituents form harmful alcohol species. The reaction products are also substantially transparent to visible light. In some instances, it can be advantageous to avoid the build up gaseous byproducts. When this is desired, R¹ and R² should be selected to have 6 or more carbon atoms so that their reaction products with water have a low vapor pressure at temperatures less than 50° C.

The reactive salt can be synthesized by reacting the corresponding Lewis acid organometallic complex [M(R¹)ₙ(R²)ₘ]⁰ with the a salt of X, e.g., (A^{+b})_{c}X. Methods for synthesizing the Lewis acid organometallic desiccant of the present invention can be found in Salt Effects in Organic and Organometallic Chemistry, VCH Publishers, Inc, New York, 1992.

Another useful set of desiccant materials includes those defined by Formula V

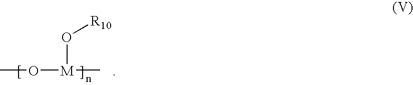

In Formula V, R₁₀ is one selected from the group including an alkyl group, an alkenyl group, an aryl group, a cycloalkyl group, a heterocyclic group, and an acyl group having at least one carbon atom, M is a trivalent metal atom, and n is an integer of two to four.

Another useful set of desiccant materials includes those defined by Formula VI

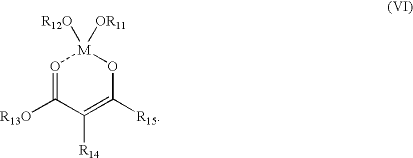

In Formula VI, each of R₁₁, R₁₂, R₁₃, R₁₄ and R₁₅ is one selected from the group including an alkyl group, an alkenyl group, an aryl group, a cycloalkyl group, a heterocyclic group, and an acyl group having at least one carbon atom, and M is a trivalent metal atom.

Another useful set of desiccant materials includes those defined by Formula VII

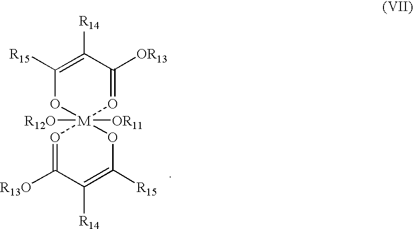

In Formula VII, each of R₁₁, R₁₂, R₁₃, R₁₄ and R₁₅ is one selected from the group including an alkyl group, an alkenyl group, an aryl group, a cycloalkyl group, a heterocyclic group, and an acyl group having at least one carbon atom, and M is a tetravalent metal atom.

Although the materials defined in Formulas V-VII form alcohols when they react with water, they can be useful in the present invention if proper precautions are taken. For example, a barrier layer between the desiccant and the OLED can be useful to stop diffusion of the alcohol. The R groups can be selected so that they are large enough to prevent any significant diffusion. Also, they can be part of a polymeric backbone that cannot diffuse.

The desiccating film host can be any number of inert materials that serves to dilute the desiccant material in order to reduce aggregation and particle formation that would normally occur for the pure desiccant material. The host can be organic or inorganic, but preferably organic.

The desiccating film host and the molecularly dispersed desiccant can be incorporated into an OLED device in numerous ways. These materials can be codeposited by thermal vapor deposition to form a film of the desiccant. The film thickness is not limited, but it is believed that a thickness range of from 0.05 microns to 500 microns is suitable, depending on the application and the required of water absorption capacity.

The desiccating film host and the molecularly dispersed desiccant can be dissolved in an organic solvent such as acetates, ketones, and cyclohexanes, and provided over the OLED device, for example by spin coating, dip coating, curtain coating, ink jet deposition, and the like. More preferably, the desiccating film host can comprise inert polymeric matrix, for example poly(butyl methacrylate), which can be cast from an organic solvent such acetates, ketones, or cyclohexanes, or mixtures thereof. A typical loading of molecularly dispersed desiccant relative to the polymer host is 0.05 to 50% by weight. Other polymers that can be used as a desiccating film host include, but are not limited to, polymethacrylates, polysiloxanes, polyvinylacetate, polystyrenes, polyacrylates, polybutadiene, or cycoloefine polymers. When the desiccating film host is a polymer or oligomer, the desiccant material can be covalently or ionicly bound to the host so long as the desiccant moieties are molecularly dispersed relative to each other. The desiccant can be part of a pendant group or incorporated into the backbone of the host polymer.

The desiccant can also be molecularly dispersed into a polymer host without the presence of solvent by heating the polymer to reduce its viscosity, and mixing in the desiccant.

General OLED Device Architecture

The present invention can be employed in most OLED device configurations where light is transmitted through a desiccant. These include very simple structures comprising a single anode and cathode to more complex devices, such as passive matrix displays comprised of orthogonal arrays of anodes and cathodes to form pixels, and active-matrix displays where each pixel is controlled independently, for example, with thin film transistors (TFTs).

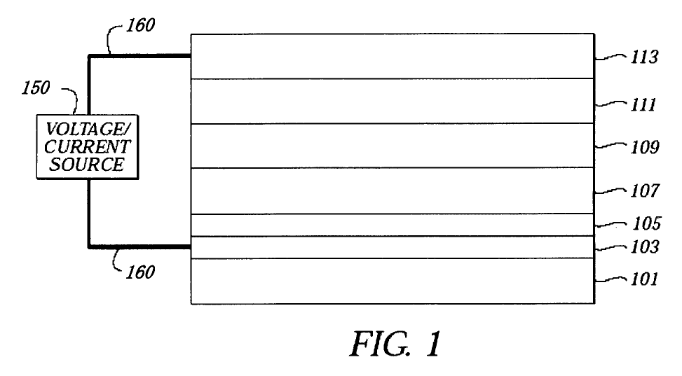

There are numerous configurations of the organic layers wherein the present invention can be successfully practiced. A schematic of a pixel area of the device, not to scale, is shown in FIG. 1. It includes a substrate 101, an anode 103, a hole-injecting layer 105, a hole-transporting layer 107, a light-emitting layer 109, an electron-transporting layer 111, and a cathode 113. These layers are described in more detail below. Note that the substrate can alternatively be located adjacent to the cathode, or the substrate can actually constitute the anode or cathode. The organic layers between the anode and cathode are conveniently referred to as the organic EL element or organic EL media. The total combined thickness of the organic layers is preferably less than 500 nm.

The anode and cathode of the OLED are connected to a voltage/current source 150 through electrical conductors 160. The OLED is operated by applying a potential between the anode and cathode such that the anode is at a more positive potential than the cathode. Holes are injected into the organic EL element from the anode and electrons are injected into the organic EL element at the anode. Enhanced device stability can sometimes be achieved when the OLED is operated in an alternating current (AC) mode where, for some time period in the cycle, the potential bias is reversed and no current flows. An example of an AC driven OLED is described in U.S. Pat. No. 5,552,678.

Substrate

The OLED device of the present invention is typically provided over a supporting substrate where either the cathode or anode can be in contact with the substrate. The substrate can have a simple or a complex structure with numerous layers, for example, a glass support with electronic elements such as TFT elements, planarizing layers, and wiring layers. The electrode in contact with the substrate is conveniently referred to as the bottom electrode. Conventionally, the bottom electrode is the anode, but the present invention is not limited to that configuration. The substrate can either be light transmissive or opaque. For applications where the EL emission is viewed through the top electrode, the transmissive characteristic of the bottom support is immaterial, and therefore can be light transmissive, light absorbing, or light reflective. Substrates for use in this case include, but are not limited to, glass, plastic, semiconductor materials, silicon, ceramics, metal foil, and circuit board materials. Of course it is necessary to provide in these device configurations a light-transparent top electrode. When EL emission is viewed through both the top and bottom electrodes, then it is necessary to provide a substrate that is light-transparent, such as glass or plastic.

Anode

When EL emission is viewed through anode 103, the anode should be transparent or substantially transparent to the emission of interest. Common transparent anode materials used in the present invention are indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is viewed only through the cathode electrode, the transmissive characteristics of anode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable way such as evaporation, sputtering, chemical vapor deposition, or electrochemical means. Anodes can be patterned using well known photolithographic processes. Optionally, anodes can be polished prior to application of other layers to reduce surface roughness so as to reduce shorts or enhance reflectivity.

Hole-Injecting Layer (HIL)

While not always necessary, it is often useful to provide a hole-injecting layer 105 between anode 103 and hole-transporting layer 107. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, plasma-deposited fluorocarbon polymers as described in U.S. Pat. Nos. 6,127,004, 6,208,075, and 6,208,077, some aromatic amines, for example, m-MTDATA (4,4′,4″-tris[(3-methylphenyl)phenylamino]triphenylamine), and inorganic oxides including vanadium oxide (VOx), molybdenum oxide (MoOx), and nickel oxide (NiOx). Alternative hole-injecting materials reportedly useful in organic EL devices are described in EP 0 891 121 A1 and EP 1 029 909 A1.

Hole-Transporting Layer (HTL)

The hole-transporting layer 107 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al. U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer can be formed of a single or a mixture of aromatic tertiary amine compounds. Illustrative of useful aromatic tertiary amines are the following:

1,1-Bis(4-di-p-tolylaminophenyl)cyclohexane;

1,1-Bis(4-di-p-tolylaminophenyl)-4-phenylcyclohexane;

N,N,N′,N′-tetraphenyl-4,4′″-diamino-1,1′:4′,1″:4″,1′″-quaterphenyl;

Bis(4-dimethylamino-2-methylphenyl)phenylmethane;

1,4-bis[2-[4-[N,N-di(p-toly)amino]phenyl]vinyl]benzene (BDTAPVB);

N,N,N′,N′-Tetra-p-tolyl-4,4′-diaminobiphenyl;

N,N,N′,N′-Tetraphenyl-4,4′-diaminobiphenyl;

N,N,N′,N′-tetra-1-naphthyl-4,4′-diaminobiphenyl;

N,N,N′,N′-tetra-2-naphthyl-4,4′-diaminobiphenyl;

N-Phenylcarbazole;

4,4′-Bis[N-(1-naphthyl)-N-phenylamino]biphenyl (NPB);

4,4′-Bis[N-(1-naphthyl)-N-(2-naphthyl)amino]biphenyl (TNB);

4,4′-Bis[N-(1-naphthyl)-N-phenylamino]p-terphenyl;

4,4′-Bis[N-(2-naphthyl)-N-phenylanino]biphenyl;

4,4′-Bis[N-(3-acenaphthenyl)-N-phenylamino]biphenyl;

1,5-Bis[N-(1-naphthyl)-N-phenylamino]naphthalene;

4,4′-Bis[N-(9-anthryl)-N-phenylamino]biphenyl;

4,4′-Bis[N-(1-anthryl)-N-phenylamino]-p-terphenyl;

4,4′-Bis[N-(2-phenanthryl)-N-phenylamino]biphenyl;

4,4′-Bis[N-(8-fluoranthenyl)-N-phenylaminolbiphenyl;

4,4′-Bis[N-(2-pyrenyl)-N-phenylamino]biphenyl;

4,4′-Bis[N-(2-naphthacenyl)-N-phenylamino]biphenyl;

4,4′-Bis[N-(2-perylenyl)-N-phenylamino]biphenyl;

4,4′-Bis[N-(1-coronenyl)-N-phenylamino]biphenyl;

2,6-Bis(di-p-tolylamino)naphthalene;

2,6-Bis[di-(1-naphthyl)amino]naphthalene;

2,6-Bis[N-(1-naphthyl)-N-(2-naphthyl)amino]naphthalene;

N,N,N′,N′-Tetra(2-naphthyl)-4,4″-diamino-p-terphenyl;

4,4′-Bis {N-phenyl-N-[4-(1-naphthyl)-phenyl]amino}biphenyl;

2,6-Bis[N,N-di(2-naphthyl)amino]fluorene;

4,4′,4″-tris[(3-methylphenyl)phenylamino]triphenylamine (MTDATA); and

4,4′-Bis[N-(3-methylphenyl)-N-phenylamino]biphenyl (TPD).

Another class of useful hole-transporting materials includes polycyclic aromatic compounds as described in EP 1 009 041. Some hole-injecting materials described in EP 0 891 121 A1 and EP 1 029 909 A1 can also make useful hole-transporting materials. In addition, polymeric hole-transporting materials can be used including poly(N-vinylcarbazole) (PVK), polythiophenes, polypyrrole, polyaniline, and copolymers including poly(3,4-ethylenedioxythiophene)/poly(4-styrenesulfonate) also called PEDOT/PSS.

Light-Emitting Layer (LEL)

As more fully described in U.S. Pat. Nos. 4,769,292 and 5,935,721, each of the light-emitting layers (LEL) of the organic EL element include a luminescent fluorescent or phosphorescent material where electroluminescence is produced as a result of electron-hole pair recombination in this region. The light-emitting layer can be comprised of a single material, but more commonly contains a host material doped with a guest emitting material or materials where light emission comes primarily from the emitting materials and can be of any color. This guest emitting material is often referred to as a light emitting dopant. The host materials in the light-emitting layer can be an electron-transporting material, as defined below, a hole-transporting material, as defined above, or another material or combination of materials that support hole-electron recombination. The emitting material is typically chosen from highly fluorescent dyes and phosphorescent compounds, e.g., transition metal complexes as described in WO 98/55561, WO 00/18851, WO 00/57676, and WO 00/70655. Emitting materials are typically incorporated at 0.01 to 10% by weight of the host material.

The host and emitting materials can be small nonpolymeric molecules or polymeric materials including polyfluorenes and polyvinylarylenes e.g., poly(p-phenylenevinylene), PPV. In the case of polymers, small molecule emitting materials can be molecularly dispersed into a polymeric host, or the emitting materials can be added by copolymerizing a minor constituent into a host polymer.

An important relationship for choosing an emitting material is a comparison of the bandgap potential which is defined as the energy difference between the highest occupied molecular orbital and the lowest unoccupied molecular orbital of the molecule. For efficient energy transfer from the host to the emitting material, a necessary condition is that the band gap of the dopant is smaller than that of the host material. For phosphorescent emitters (including materials that emit from a triplet excited state, i.e., so-called “triplet emitters”) it is also important that the host triplet energy level of the host be high enough to enable energy transfer from host to emitting material.

Host and emitting materials known to be of use include, but are not limited to, those disclosed in U.S. Pat. Nos. 4,768,292, 5,141,671, 5,150,006, 5,151,629, 5,405,709, 5,484,922, 5,593,788, 5,645,948, 5,683,823, 5,755,999, 5,928,802, 5,935,720, 5,935,721, 6,020,078, 6,475,648, 6,534,199, 6,661,023, U.S. Patent Application Publications 2002/0127427 A1, 2003/0198829 A1, 2003/0203234 A1, 2003/0224202 A1, and 2004/0001969 A1.

Metal complexes of 8-hydroxyquinoline (oxine) and similar derivatives constitute one class of useful host compounds capable of supporting electroluminescence. Illustrative of useful chelated oxinoid compounds are the following:

CO-1: Aluminum trisoxine [alias, tris(8-quinolinolato)aluminum(III)];

CO-2: Magnesium bisoxine [alias, bis(8-quinolinolato)magnesium(II)];

CO-3: Bis[benzo{f}-8-quinolinolato]zinc (II);

CO-4: Bis(2-methyl-8-quinolinolato)aluminum(III)-R-oxo-bis(2-methyl-8-quinolinolato)aluminum(III);

CO-5: Indium trisoxine [alias, tris(8-quinolinolato)indium];

CO-6: Aluminum tris(5-methyloxine)[alias, tris(5-methyl-8-quinolinolato)aluminum(III)];

CO-7: Lithium oxine [alias, (8-quinolinolato)lithium(I)];

CO-8: Gallium oxine [alias, tris(8-quinolinolato)gallium(III)]; and

CO-9: Zirconium oxine [alias, tetra(8-quinolinolato)zirconium(IV)].

Another class of useful host materials includes derivatives of anthracene, such as those described in U.S. Pat. Nos. 5,935,721, 5,972,247, 6,465,115, 6,534,199, 6,713,192, U.S. Patent Application Publications 2002/0048687 A1, 2003/0072966 A1, and WO 2004018587. Some examples include derivatives of 9,10-dinaphthylanthracene derivatives and 9-naphthyl-10-phenylanthracene. Other useful classes of host materials include distyrylarylene derivatives as described in U.S. Pat. No. 5,121,029, and benzazole derivatives, for example, 2,2′,2″-(1,3,5-phenylene)tris[1-phenyl-1H-benzimidazole].

Desirable host materials are capable of forming a continuous film. The light-emitting layer can contain more than one host material in order to improve the device's film morphology, electrical properties, light emission efficiency, and lifetime. Mixtures of electron-transporting and hole-transporting materials are known as useful hosts. In addition, mixtures of the above listed host materials with hole-transporting or electron-transporting materials can make suitable hosts.

Useful fluorescent dopants include, but are not limited to, derivatives of anthracene, tetracene, xanthene, perylene, rubrene, coumarin, rhodamine, and quinacridone, dicyanomethylenepyran compounds, thiopyran compounds, polymethine compounds, pyrilium and thiapyrilium compounds, fluorene derivatives, periflanthene derivatives, indenoperylene derivatives, bis(azinyl)amine boron compounds, bis(azinyl)methane compounds, derivatives of distryrylbenzene and distyrylbiphenyl, and carbostyryl compounds. Among derivatives of distyrylbenzene, particularly useful are those substituted with diarylamino groups, informally known as distyrylamines.

Suitable host materials for phosphorescent emitters (including materials that emit from a triplet excited state, i.e., so-called “triplet emitters”) should be selected so that the triplet exciton can be transferred efficiently from the host material to the phosphorescent material. For this transfer to occur, it is a highly desirable condition that the excited state energy of the phosphorescent material be lower than the difference in energy between the lowest triplet state and the ground state of the host. However, the band gap of the host should not be chosen so large as to cause an unacceptable increase in the drive voltage of the OLED. Suitable host materials are described in WO 00/70655 A2; WO 01/39234 A2; WO 01/93642 A1; WO 02/074015 A2; WO 02/15645 A1, and U.S. Patent Application Publication 2002/0117662 A1. Suitable hosts include certain aryl amines, triazoles, indoles, and carbazole compounds. Examples of desirable hosts are 4,4′-N,N′-dicarbazole-biphenyl (CBP), 2,2′-dimethyl-4,4′-N,N′-dicarbazole-biphenyl, m-(N,N′-dicarbazole)benzene, and poly(N-vinyl-carbazole), including their derivatives.

Examples of useful phosphorescent materials that can be used in light-emitting layers of the present invention include, but are not limited to, those described in WO 00/57676, WO 00/70655, WO 01/41512 A1, WO 02/15645 A1, WO 01/93642 A1, WO 01/39234 A2, WO 02/071813 A1, WO 02/074015 A2, U.S. Pat. Nos. 6,458,475, 6,451,455, 6,573,651, 6,413,656, 6,515,298, 6,451,415, 6,097,147, EP 1 239 526 A2, EP 1 238 981 A2, EP 1 244 155 A2, JP 2003059667A, JP 2003073665A, JP 2003073387A, JP 2003 073388A, U.S. Patent Application Publications 2003/0017361 A1, 2002/0197511 A1, 2003/0072964 A1, 2003/0068528 A1, 2003/0124381 A1, 2003/0059646 A1, 2003/0054198 A1, 2002/0100906 A1, 2003/0068526 A1, 2003/0068535 A1, 2003/0141809 A1, 2003/0040627 A1, and 2002/0121638 A1.

Electron-Transporting Layer (ETL)

Preferred thin film-forming materials for use in forming the electron-transporting layer 111 of the organic EL elements of the present invention are metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

Cathode

When light emission is viewed solely through the anode, the cathode 113 used in the present invention can be comprised of nearly any conductive material. Desirable materials have effective film-forming properties to ensure effective contact with the underlying organic layer, promote electron injection at low voltage, and have effective stability. Useful cathode materials often contain a low work function metal (<4.0 eV) or metal alloy. One preferred cathode material is comprised of a Mg:Ag alloy wherein the percentage of silver is in the range of from 1 to 20%, as described in U.S. Pat. No. 4,885,221. Another suitable class of cathode materials includes bilayers comprising a thin electron-injection layer (EIL) in contact with the organic layer (e.g., ETL), which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861, 5,059,862, and 6,140,763.

A metal-doped organic layer can be used as an electron-injecting layer. Such a layer contains an organic electron-transporting material and a low work-function metal (<4.0 eV). For example, Kido et al. reported in “Bright Organic Electroluminescent Devices Having a Metal-Doped Electron-Injecting Layer”, Applied Physics Letters, 73, 2866 (1998) and disclosed in U.S. Pat. No. 6,013,384 that an OLED can be fabricated containing a low work-function metal-doped electron-injecting layer adjacent to a cathode. Suitable metals for the metal-doped organic layer include alkali metals (e.g. lithium, sodium), alkaline earth metals (e.g. barium, magnesium), or metals from the lanthanide group (e.g. lanthanum, neodymium, lutetium), or combinations thereof. The concentration of the low work-function metal in the metal-doped organic layer is in the range of from 0.1% to 30% by volume. Preferably, the concentration of the low work-function metal in the metal-doped organic layer is in the range of from 0.2% to 10% by volume. Preferably, the low work-function metal is provided in a mole ratio in a range of from 1:1 with the organic electron transporting material.

When light emission is viewed through the cathode, the cathode should be transparent or nearly transparent. For such applications, metals should be thin or one should use transparent conductive oxides, or include these materials. Optically transparent cathodes have been described in more detail in U.S. Pat. Nos. 4,885,211, 5,247,190, 5,703,436, 5,608,287, 5,837,391, 5,677,572, 5,776,622, 5,776,623, 5,714,838, 5,969,474, 5,739,545, 5,981,306, 6,137,223, 6,140,763, 6,172,459, 6,278,236, 6,284,393, JP 3,234,963, and EP 1 076 368. Cathode materials are typically deposited by evaporation, sputtering, or chemical vapor deposition. When needed, patterning can be achieved through many well known methods including, but not limited to, through-mask deposition, integral shadow masking, for example, as described in U.S. Pat. No. 5,276,380 and EP 0 732 868, laser ablation, and selective chemical vapor deposition.

Other Common Organic Layers and Device Architecture

In some instances, layers 109 and 111 can optionally be collapsed into a single layer that serves the function of supporting both light emission and electron transportation. It also known in the art that emitting dopants can be added to the hole-transporting layer, which can serve as a host. Multiple dopants can be added to one or more layers in order to produce a white-emitting OLED, for example, by combining blue- and yellow-emitting materials, cyan- and red-emitting materials, or red-, green-, and blue-emitting materials. White-emitting devices are described, for example, in EP 1 187 235, EP 1 182 244, U.S. Pat. Nos. 5,683,823, 5,503,910, 5,405,709, 5,283,132, 6,627,333, U.S. Patent Application Publications 2002/0186214 A1, 2002/0025419 A1, and 2004/0009367 A1.

Additional layers such as exciton, electron and hole-blocking layers as taught in the art can be employed in devices of the present invention. Hole-blocking layers are commonly used to improve efficiency of phosphorescent emitter devices, for example, as in U.S. Patent Application Publications 2002/0015859 A1, 2003/0068528 A1, 2003/0175553 A1, WO 00/70655A2, and WO 01/93642A1.

The present invention can be used in so-called stacked device architecture, for example, as taught in U.S. Pat. Nos. 5,703,436, 6,337,492, 6,717,358, and U.S. Patent Application Publication 2003/0170491 A1.

Deposition of Organic Layers

The organic materials mentioned above are suitably deposited through a vapor phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimation “boat” often comprised of a tantalum material, e.g., as described in U.S. Pat. No. 6,237,529, or can be first coated onto a donor sheet and then sublimed in closer proximity to the substrate. Layers with a mixture of materials can use separate sublimation boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,688,551, 5,851,709 and 6,066,357), and inkjet method (U.S. Pat. No. 6,066,357).

Optical Optimization

OLED devices of the present invention can employ various well known optical effects in order to enhance its properties if desired. This includes optimizing layer thicknesses to yield maximum light transmission, providing dielectric mirror structures, replacing reflective electrodes with light-absorbing electrodes, providing anti glare or anti-reflection coatings over the display, providing a polarizing medium over the display, or providing colored, neutral density, or color conversion filters in functional relationship with the light emitting areas of the display. Filters, polarizers, and anti-glare or anti-reflection coatings can also be provided over a cover or as part of a cover. It will be understood that color filters can formed on the cover glass or internally within the device itself, for example, over the inorganic barrier layer discussed later.

The OLED device can have a microcavity structure. In one useful example, one of the metallic electrodes is essentially opaque and reflective; the other one is reflective and semitransparent. The reflective electrode is preferably selected from Au, Ag, Mg, Ca, or alloys thereof. Because of the presence of the two reflecting metal electrodes, the device has a microcavity structure. The strong optical interference in this structure results in a resonance condition. Emission near the resonance wavelength is enhanced and emission away from the resonance wavelength is depressed. The optical path length can be tuned by selecting the thickness of the organic layers or by placing a transparent optical spacer between the electrodes. For example, an OLED device of the present invention can have ITO spacer layer placed between a reflective anode and the organic EL media, with a semitransparent cathode over the organic EL media.

Encapsulation

As stated, OLED devices are sensitive to moisture or oxygen, or both, so they are commonly sealed in an inert atmosphere such as nitrogen or argon. In sealing an OLED device in an inert environment, a protective cover can be attached using an organic adhesive, a metal solder, or a low melting temperature glass. The desiccant is also provided within the sealed space over the OLED and in the path of light emission. The desiccant film of the present invention can be used in combination with other getters and desiccants including, for example, alkali and alkaline metals, alumina, bauxite, calcium sulfate, clays, silica gel, zeolites, alkaline metal oxides, alkaline earth metal oxides, sulfates, or metal halides and perchlorates. In addition, the desiccant film can be used in combination with barrier layers such as SiOx, Teflon, and alternating inorganic/polymeric layers as known in the art. Barrier layers can be provided over the OLED, between the OLED and a flexible substrate, or both. Barrier layers provided in association with the desiccant film in areas of light emission should be transparent.

Some non-limiting examples of inorganic barrier layer materials include metal oxides such as silicon oxides and aluminum oxides, and metal nitrides such as silicon nitride. Suitable examples of inorganic barrier layer materials include aluminum oxide, silicon dioxide, silicon nitride, silicon oxynitride, and diamond-like carbon. In some circumstances it is useful if the inorganic barrier layer material can be electronically conductive, such as a conductive metal oxide, a metal or metal alloy. In this case, the conductive inorganic barrier layer can carry current to one or more device electrodes, serve as the electrode, or provide a way for discharging static electricity. Metals such as Al, Ag, Au, Mo, Cr, Pd, or Cu, or alloys containing these metals can be useful inorganic barrier layers. Multiple layers of metal can be used to fabricate a conductive inorganic barrier layer. Where unwanted shorting can occur, conductive barrier layers should not be used, or they should be patterned, e.g., with a shadow mask, such that they do not cause shorting. The inorganic barrier layer is typically provided in a thickness of 10 to several hundreds of nanometers.

Useful techniques of forming layers of inorganic barrier layer material from a vapor phase include, but are not limited to, thermal physical vapor deposition, sputter deposition, electron beam deposition, chemical vapor deposition (CVD), plasma-enhanced chemical vapor deposition, laser-induced chemical vapor deposition, and atomic layer deposition (ALD). CVD and ALD are particularly useful. In some instances, said materials can be deposited from a solution or another fluidized matrix, e.g., from a super critical solution of CO₂. Care should be taken to choose a solvent or fluid matrix does not negatively affect the performance of the device. Patterning of said materials can be achieved through many way including but not limited to photolithography, lift-off techniques, laser ablation, and more preferably, through shadow mask technology.

The organic barrier layer material can be monomeric or polymeric, and can be deposited using vapor deposition or from solution. If cast from solution, it is important that the deposition solution does not negatively affect the OLED device.

Conveniently, the organic barrier layer is made of a polymeric materials such as parylene materials, which can be deposited from a vapor phase to provide a polymer layer having excellent adhesion to, and step coverage over, topological features of the OLED devices, including defects such as particulate defects. The organic barrier layer is typically formed in a thickness range of from 0.01 to 5 micrometer. However, by their very nature, the organic materials in the organic barrier layer exhibit more moisture permeability than a layer formed of an inorganic dielectric material or a layer formed of a metal. Thus, it is often desirable to encase the organic barrier layer with an inorganic material.

### Embodiments

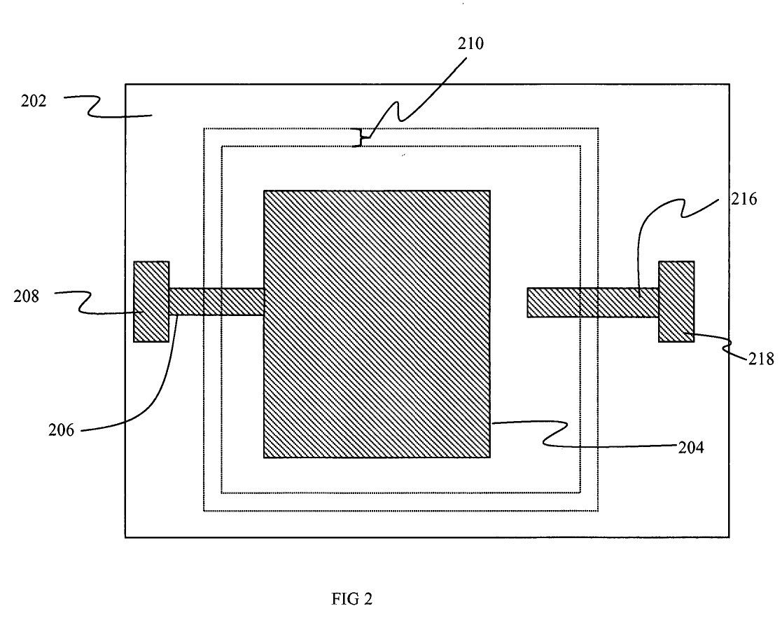

As a first embodiment, FIGS. 2-4B illustrate various stages of the fabrication of an OLED device 200A. Turning first to FIG. 2, a top view of an OLED substrate 202 is shown. A predetermined seal area 210 is represented by the space between the dotted lines in FIG. 2. The inner dotted line further represents the sealed region of the OLED device. Over OLED substrate 202 are provided a first electrode 204, a first electrical contact pad 208, and a first interconnect line 206 that provides an electrical connection between the first electrode 204 and the first electrical contact pad 208. The first interconnect line 206 extends through the seal area. As discussed later, the first electrode 204 can be the anode or cathode, and can be any number of well known conductive materials, as discussed above. The conductive material used for each of the first electrode 204, the first interconnect line 206, and the first electrical contact pad 208 can be the same or different. In addition, each of the first electrode 204, the first interconnect line 206, and the first electrical contact pad 208 can contain two or more layers of different conductive materials.

A second interconnect line 216 and a second contact pad 218 are provided over the OLED substrate 202 to provide a way for making electrical contact to a second electrode that is formed in a later step. The conductive material used for the second contact pad 218 and second interconnect line 216 can be the same or different, and can also be the same or different from the material(s) used as the first electrical contact pad 208 and first interconnect line 206.

The conductive materials for forming the first electrode 204, the first and second interconnect lines, and the first and second contact pads can be deposited by vacuum methods such as thermal physical vapor deposition, sputter deposition, plasma-enhanced chemical vapor deposition, electron-beam assisted vapor deposition, and other methods known in the art. In addition, so-called “wet” chemical processes can be used such as electroless and electrolytic plating. The first electrode 204, the first interconnect line 206, the first electrical contact pad 208, the second interconnect line 216, and the second contact pad 218 can be provided in the same patterning step or different patterning steps. Patterning can be achieved by deposition through a shadow mask, photolithographic methods, laser ablation, selective electroless plating, electrochemical etching, and other well known patterning techniques.

The first electrode 204, interconnect lines 206 and 216, and contact pads 208 and 218 are made from aluminum. In this arrangement, the first electrode functions as the anode, is reflective and opaque. In order to provide a high work function surface for effective hole injection, a layer of indium-doped tin oxide (ITO) is provided over the anode (not shown). The second contact pad 218 and second interconnect line 216 are made from aluminum in this arrangement.

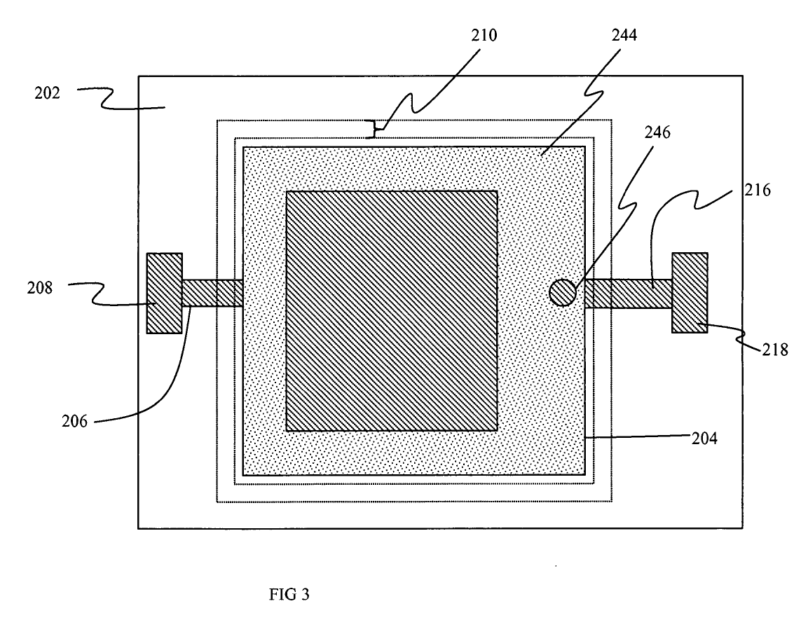

Turning now to FIG. 3, an insulation layer 244 is provided in a pattern over the OLED substrate 202. The insulation layer 244 extends over a portion of the first electrode 204 and over at least a portion of the first and second interconnects, 206 and 216. A via 246 is provided over the second interconnect line 216 that is located inside the sealed region. The insulation layer 244 does not extend through the predetermined seal area 210 in this arrangement.

The insulation layer 244 can be any number of organic or inorganic materials provided that the material has low electrical conductivity and provides effective adhesion with the surfaces over which it is applied. The insulation layer 244 acts to reduce shorting that can occur between first and second electrodes, and can provide planarization. Insulation layer 244 is typically provided in a thickness of from a few nanometers to a few microns. Many of the same materials and deposition methods can be used to form the insulation layer 244 as described above for barrier layer materials.

Some examples of organic materials that are useful for the insulation layer 244 include polyimides, parylene, and acrylate-based photoresist materials. Some examples of inorganic materials that are useful for the insulation layer 244 include metal oxides such as silicon oxides and aluminum oxides, and metal nitrides such as silicon nitride and ceramic composites. In addition, the materials can be provided from a solution, such as a sol-gel. For the purposes of discussion, a sol-gel material that has high planarizing ability is used as the insulation layer 244 in this arrangement.

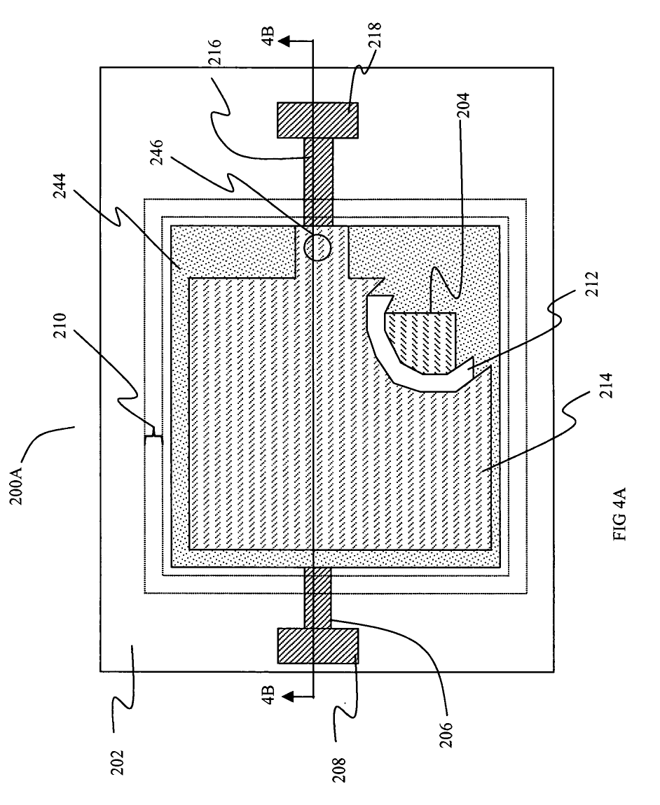

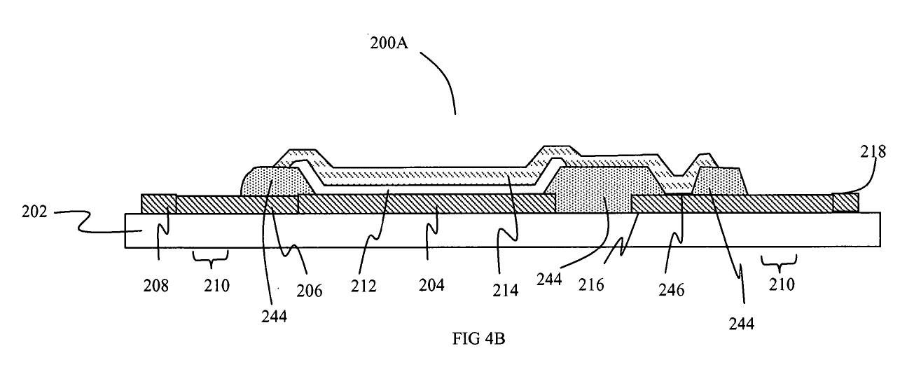

As shown in FIG. 4A, the organic EL media layer 212 and second electrode 214 are then deposited to make OLED device 200A. To illustrate the layer order, the lower right corner of first electrode area is pictorially cut away to show the first electrode 104. A cross-sectional view taken along lines 4B is shown in FIG. 4B. The second electrode is the cathode and is semitransparent. It is made from a thin layer of Li (e.g., 1 nm) in contact with the organic EL media, a thin layer of Al (e.g., 10 nm) over the lithium, and a thicker layer of ITO (e.g. 100 nm) over the Al. The cathode makes contact to the second interconnect line 216 in the via.

To illustrate the layer order, the lower right corner of first electrode area is pictorially cut away to show the first electrode 204. The organic EL media layer 212 is described in more detail below, but it can contain one or several layers of different materials. The organic EL media layer 212 is provided over the entire first electrode 204 and over a portion of the insulation layer 244. The organic EL media layer does not extend into the via 246 or through the predetermined seal area 210. The second electrode 214 is patterned over the first electrode and into the via 246, but does not contact the first interconnect line 206. The light-emitting area (pixel) is defined by the area of overlap of the first electrode 204 with the second electrode 214, wherein there is organic EL media sandwiched there between. Because the first electrode is reflective and opaque, and the second electrode is semitransparent, this light will emit in a direction away from OLED substrate 202. This is referred to as a “top-emitting” OLED. The second electrode 214 can be deposited and patterned using methods previously described.

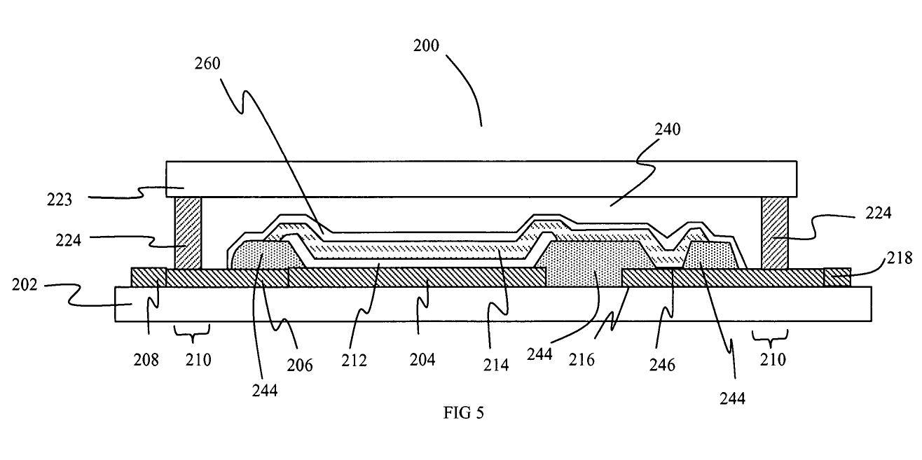

Turning now to FIG. 5, a top-emitting, encapsulated OLED device 200 is shown. Where elements correspond to those in FIG. 4B, the same reference numerals will be used. A light transmissive desiccating film 260 is provided over the second electrode of the OLED device, which includes a host and molecularly dispersed desiccant material previously discussed. Although not necessary, it can be advantageous for the light transmissive desiccating film 260 to be deposited by vapor deposition in order to avoid subjecting the organic EL media to possible contamination by solvents. If desiccant is deposited from solution, the second electrode and the insulating layer should be selected so that they are compatible with the solvent and do not permit transmission of desiccant solution into the organic EL media layer.

A cover 223 is made of glass and provided having deposited thereon a seal material 224 in a pattern corresponding to the predetermined seal area 210. The cover 223 with the patterned seal material 224 is provided over the OLED device 200A in alignment with the predetermined seal area 210. Pressure is applied between the OLED substrate 202 and cover 223 while the seal material is cured or fused. The sealing step is preferably done under inert conditions such as under vacuum or under a dry nitrogen or argon atmosphere. The nitrogen or argon atmosphere can be at a pressure lower than atmospheric pressure. If the sealing step is done under nitrogen or argon, this space is filled with these gasses. If the pressure in space 240 is slightly reduced relative to atmospheric pressure, there can be an advantage of maintaining a pressure between the cover and the OLED substrate to ensure an effective seal. Further, if the space 240 is under slightly reduced pressure, then there is less chance of seal failure if the encapsulated OLED device is exposed to low pressures (e.g., transportation in the cargo bay of an airplane).

Alternatively, the seal material 224 can be provided on the OLED device 200A in the predetermined seal area 210, and then the cover is applied and sealed. The cover is preferably transparent glass in this arrangement. A transparent polymer cover can also be used if it is provided with a water impermeable layer(s) adjacent to the interface with the seal material.

The seal material 224 can be an organic adhesive such as UV or heat cured epoxy resin, acrylates, or pressure sensitive adhesive. Alternatively, the seal material can be a glass frit seal material or a metal solder. Such seals are activated by heating, for example with a laser, to cause the material to flow. A seal is formed when the seal material re-solidifies. It is desirable to maintain the sealing temperature as low as possible because OLED devices have thermally sensitive parts and coatings. Glass frit seal material can be lead-based, e.g., based on PbO—ZnO—B₂O₃. Preferably, the glass frit seal material is lead-free, e.g., based on ZnO—SnO—P₂O₅. The seal material should also provide a coefficient of thermal expansion (CTE) that is compatible with the CTE of the substrate.

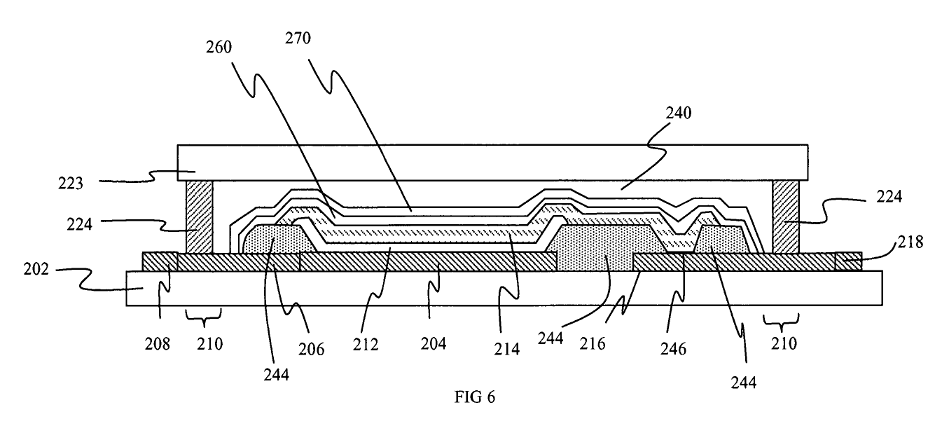

A second embodiment of the present invention is shown in FIG. 6. The device of FIG. 6 is analogous to that of FIG. 5, except that a transparent barrier layer 270 is provided over the light transmissive desiccating film 260. As described previously, the barrier layer can be a single layer or a plurality of sublayers, for example, alternating inorganic/organic sublayers. In a preferred arrangement, the transparent barrier layer 270 has three sublayers (not shown) made of Al₂O₃/parylene/Al₂O₃.

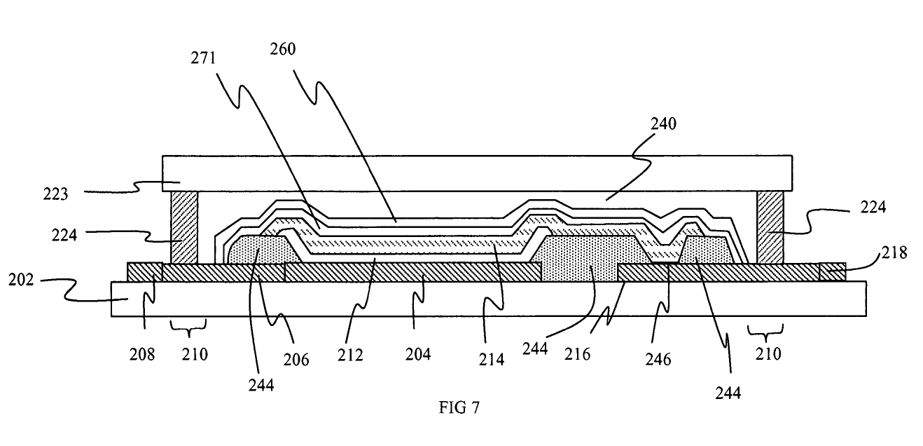

A third embodiment of the present invention is shown in FIG. 7. The device of FIG. 7 is analogous to that of FIG. 6, except that a transparent barrier layer 271 is provided over the OLED device first, and the light transmissive desiccating film 260 is provided over the transparent barrier layer 271. In addition to producing an additional barrier to moisture penetration, transparent barrier layer 271 can protect the OLED from solvents or chemical reactions associated with the light transmissive desiccating film.

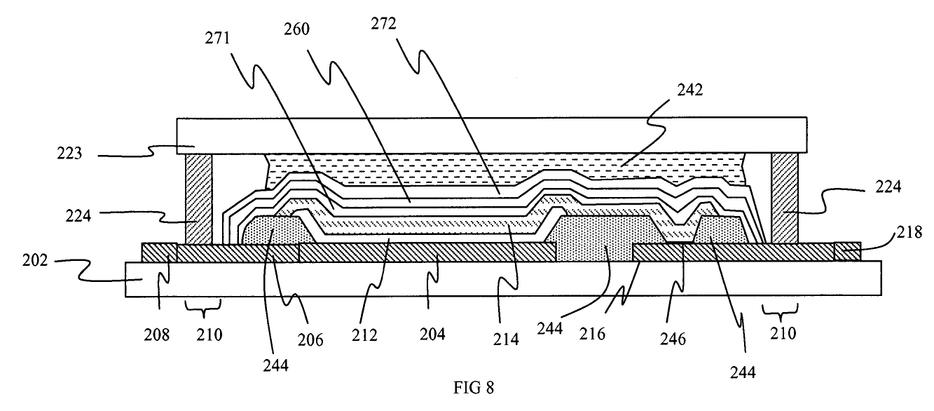

A fourth embodiment of the present invention is shown in FIG. 8. The device of FIG. 8 is analogous to that of FIG. 7, except that a transparent second barrier layer 272 has been provided over light transmissive desiccating film 260. FIG. 8 shows a transparent polymer buffer layer 242 provided in a fashion analogous to that shown in FIG. 7. All of the embodiments mentioned above can use this polymer buffer layer.

The transparent polymer buffer layer 242 is selected to be transparent or nearly transparent, and having this layer between the cathode and the cover can improve optical out-coupling. The transparent polymer buffer layer 242 can be any number of materials including UV or heat cured epoxy resin, acrylates, or pressure sensitive adhesive. An example of a useful UV-curable epoxy resin is Optocast 3505 from Electronic Materials Inc. An example of useful pressure sensitive adhesive is Optically Clear Laminating Adhesive 8142 from 3M. The polymer buffer layer can also serve a dual role as the light transmissive desiccating film.

The invention has been described in detail with particular reference to certain preferred embodiments thereof, but it will be understood that variations and modifications can be effected within the spirit and scope of the invention.

### PARTS LIST

101 substrate
103 anode
105 hole-injecting layer
107 hole-transporting layer
109 light-emitting layer
111 electron-transporting layer
113 cathode
150 voltage/current source
160 electrical conductors
200 encapsulated OLED device
200A OLED device
202 OLED substrate
204 first electrode
206 first interconnect line
208 first electrical contact pad
210 seal area
212 organic EL media layer
214 second electrode
216 second interconnect line
218 second contact pad
223 cover
224 seal material
240 space
242 transparent polymer buffer layer
244 insulation layer
246 via
260 light transmissive desiccating film
270 transparent barrier layer
271 transparent barrier layer
272 transparent second barrier layer

1. A top-emitting OLED device comprising:
a) a substrate;
b) a first electrode disposed over the substrate;
c) an organic EL media disposed over the first electrode;
d) a transparent or semitransparent second electrode disposed over the organic EL media; and
e) a light transmissive desiccating film having a host and molecularly dispersed desiccant material in such host provided on or over the second electrode.

2. The top-emitting OLED device of claim 1 including a transparent inorganic barrier layer disposed between the second electrode and the light transmissive desiccating film or on the light transmissive desiccating film.

3. The top-emitting OLED device of claim 1 wherein the molecularly dispersed desiccant material is selected to be transparent before and after absorbing water.

4. The top-emitting OLED device of claim 1 further including providing a cover made of glass over the light transmissive desiccating film.

5. The top-emitting OLED device of claim 1 wherein the desiccant material includes a Lewis acid organometallic structure having the formula
R¹ₙ-M-R²ₘ (I)
wherein:
M is a metal;
R¹ is an organic substituent wherein at least one carbon is directly bonded to the metal;
R² is a silyl oxide substituent wherein the oxygen is directly bonded to the metal, or an amide substituent having a nitrogen directly bonded to the metal; and
n=1, 2, 3, or 4 and m=0, 1, 2, or 3 and are selected to fulfill the coordination requirements of M so that Formula I is neutral in charge.

6. The top-emitting OLED device of claim 1 wherein the desiccant material includes a reactive salt of a negatively charged organometallic complex that, when it reacts with water, forms a carbon-hydrogen bond but does not form an alcohol having the formula
(A^{+b})_{c}[M(R¹)ₙ(R²)ₘ(X)ₗ]^{-q}
wherein:
A is a cation having charge b;
M is a metal;
R¹ is an organic substituent wherein at least one carbon is directly bonded to the metal;
R² is a silyl oxide wherein the oxygen is directly bonded to the metal, or an amide having a nitrogen directly bonded to the metal;
X is an anionic substituent having a pKa<7;
l=1 or 2
n=1, 2, 3, or 4;
m=0, 1, 2, or 3;
q=is the charge of the anionic organometallic complex and is 1 or 2; and
b=q/c.

7. The top-emitting OLED device of claim 1 wherein the desiccant material has the formula 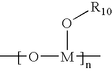
wherein:
R₁₀ is one selected from the group including an alkyl group, an alkenyl group, an aryl group, a cycloalkyl group, a heterocyclic group, and an acyl group having at least one carbon atom;
M is a trivalent metal atom; and
n is an integer of two to four.

8. The top-emitting OLED device of claim 1 wherein the desiccant material has the formula 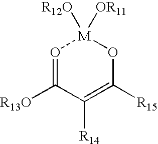
wherein:
each of R¹¹, R₁₂, R₁₃, R₁₄ and R₁₅ is one selected from the group including an alkyl group, an alkenyl group, an aryl group, a cycloalkyl group, a heterocyclic group, and an acyl group having at least one carbon atom; and
M is a trivalent metal atom.

9. The top-emitting OLED device of claim 1 wherein the desiccant material has the formula 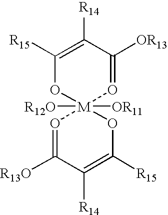
wherein:
each of R₁₁, R₁₂, R₁₃, R₁₄ and R₁₅ is one selected from the group including an alkyl group, an alkenyl group, an aryl group, a cycloalkyl group, a heterocyclic group, and an acyl group having at least one carbon atom; and
M is a tetravalent metal atom.

10. The top-emitting OLED device of claim 1 wherein the host includes a polymer.

11. The top-emitting OLED device of claim 2 wherein the inorganic barrier layer includes metal oxides or nitrides, or both, and are deposited by thermal physical vapor deposition, sputtering, chemical vapor deposition, plasma enhanced chemical vapor deposition, or atomic layer deposition.
